(19) United States
(12) Patent Application Publication
(10) Pub. No.: US 2008/0037223 A1
(43) Pub. Date: Feb. 14, 2008

(54) Power Electronics with a Heat Sink

(75) Inventors: Alexander Muller, Bad Waldsee-Reute (DE); Harald Rapp, Wangen Im Allgau (DE)

Correspondence Address: LERNER GREENBERG STEMER LLP, P O BOX 2480, HOLLYWOOD, FL, 33022-2480, US

(73) Assignee: DIEHL AKO STIFTUNG & CO. KG, Wangen (DE)

(21) Appl. No.: 11/837,579

(22) Filed: Aug. 13, 2007

(30) Foreign Application Priority Data
Aug. 12, 2006 (DE) DE102006037825.3
Dec. 22, 2006 (DE) DE102006061215.9

(51) Int. Cl. H05K 7/20

(52) U.S. Cl. 361/710

(57) ABSTRACT

Power electronics include a printed circuit board on which at least one component to be cooled is mounted, and a heat sink which is arranged on that side of the printed circuit board which faces the component to be cooled. The heat sink is in thermally conductive contact with the component to be cooled. In order to allow the power electronics to be produced and assembled easily, they furthermore have a positioning device for positioning the printed circuit board in a defined orientation relative to the heat sink, where the distance between the heat sink and the printed circuit board corresponds approximately to the physical height of the at least one component to be cooled, and at least one attachment element for attaching the printed circuit board to the heat sink and at the same time for pressing the at least one component to be cooled against the heat sink.

### CROSS-REFERENCE TO RELATED APPLICATION

This application claims the priority, under 35 U.S.C. §119, of German application DE 10 2006 037 825.3, filed Aug. 12, 2006; the prior application is herewith incorporated by reference in its entirety.

### BACKGROUND OF THE INVENTION

### Field of the Invention

The present invention relates to power electronics, in particular to power electronics with a heat sink. Such power electronics are used, by way of example, for washing machine drives.

Power electronics contain semiconductor components, so-called power modules, which have to be cooled during operation. This task is conventionally carried out by way of heat sinks composed of metal which are pressed by means of suitable attachment means directly against the components to be cooled, thus ensuring a good heat transfer. The power modules are mounted on a printed circuit board, which is likewise connected to the heat sink by way of suitable attachment means.

By way of example, European published patent application EP 0 632 686 A1 discloses each power module on a printed circuit board that is provided with its own heat sink, which is pressed against the upper face of the component via spring tongues that are integrally formed on a frame, by means of this frame, which surrounds the component to be cooled and is mounted on the printed circuit board.

Furthermore, German published patent application DE 199 46 354 A1 describes the mounting of a printed circuit board and of an extruded heat sink on a common robust basic mount, which unit can then be installed in a housing, in a chassis.

European published patent application EP 0 483 058 A1 discloses a specific heat sink with hollow-profile cooling ribs composed of extruded aluminium, which has an increased rib ratio.

The two last-mentioned documents do not contain any further details relating to the thermal coupling of components to be cooled on the printed circuit board to the heat sink.

The shape of the heat sink and the connection of the printed circuit board and power modules to the heat sink are the major cost drivers in the manufacture and assembly of power electronics. There is therefore a need for skilful design of the heat sink and electronic components, in order to minimize the manufacturing costs for power electronics.

### SUMMARY OF THE INVENTION

It is accordingly an object of the invention to provide a power electronics with a heat sink which overcomes the above-mentioned disadvantages of the heretofore-known devices and methods of this general type and which provides for a heat sink that can be produced and fitted easily. The power electronics are expediently intended to be suitable not only for simple manual assembly, but also for automation.

With the foregoing and other objects in view there is provided, in accordance with the invention, a power electronics, comprising:

a printed circuit board having mounted thereon at least one component to be cooled;

a heat sink disposed on said printed circuit board and in thermally conductive contact with the at least one component to be cooled;

a positioning device for positioning said printed circuit board in a defined orientation relative to said heat sink and with a spacing distance between said heat sink and said printed circuit board approximately corresponding to a physical height of the at least one component to be cooled; and

at least one attachment element for attaching said printed circuit board to said heat sink and for pressing the at least one component to be cooled against said heat sink.

The power electronics have a printed circuit board on which at least one component to be cooled is mounted, and a heat sink which is arranged on that side of the printed circuit board which faces the component to be cooled, in thermally conductive contact with the component to be cooled. A positioning device positions the printed circuit board in a defined orientation and spacing relative to the heat sink, where the distance between the heat sink and the printed circuit board corresponds approximately to the physical height of the at least one component to be cooled. The novel assembly includes at least one attachment element for attaching the printed circuit board to the heat sink and at the same time for pressing the at least one component to be cooled against the heat sink.

The positioning device allows the printed circuit board with the components to be cooled and the heat sink to be preassembled in their desired orientation with respect to one another. It is then possible to use the attachment elements not only to attach the printed circuit board to the heat sink but also to produce a good thermal contact between the components to be cooled on the printed circuit board and the heat sink, in one process. Only a small number of components and production steps are required with this design for mounting the printed circuit board and the components to be cooled on the heat sink, thus simplifying the manufacture and assembly of the power electronics, and allowing the overall production costs to be reduced.

In one refinement of the invention, the positioning device has a groove which is provided in a wall section of the heat sink and into which the printed circuit board can be pushed, and which is at a predefined distance from the heat sink surface, and a stop, which is provided on the printed circuit board, for defining the (maximum) insertion depth of the printed circuit board into the groove. This positioning device can be used to (pre)install the components in a simple manner precisely in the desired orientation with respect to one another.

In a further refinement of the invention, the at least one attachment element is a self-tapping screw, and the heat sink has at least one slot on its side facing the printed circuit board, into which slot the self-tapping screw can be screwed.

At least one attachment element preferably presses one component to be cooled against the heat sink via the printed circuit board, so that the printed circuit board is attached to the heat sink at the same time. In this case, at least one further attachment element can press a further component to be cooled directly against the heat sink.

In the preferred embodiment of the invention, the heat sink has a multiplicity of cooling ribs on its side facing away from the printed circuit board.

In one particularly preferred embodiment, the heat sink is an extruded part, which can be produced easily, and wherein the cooling ribs, the slots, the wall section and the groove run parallel to one another.

In yet another refinement of the invention, the printed circuit board and its components are at least partially lacquered or encapsulated.

The power electronics according to the invention can advantageously be used as power electronics for a washing machine drive.

Other features which are considered as characteristic for the invention are set forth in the appended claims.

Although the invention is illustrated and described herein as embodied in power electronics with a heat sink, it is nevertheless not intended to be limited to the details shown, since various modifications and structural changes may be made therein without departing from the spirit of the invention and within the scope and range of equivalents of the claims.

The construction and method of operation of the invention, however, together with additional objects and advantages thereof will be best understood from the following description of specific embodiments when read in connection with the accompanying drawings.

### BRIEF DESCRIPTION OF THE SEVERAL VIEWS OF THE DRAWING

FIG. 1 is a schematic plan view of The power electronics according to one exemplary embodiment; and

FIG. 2 shows a section taken through the power electronics along the line II-II in FIG. 1 and viewed in the direction of the arrows.

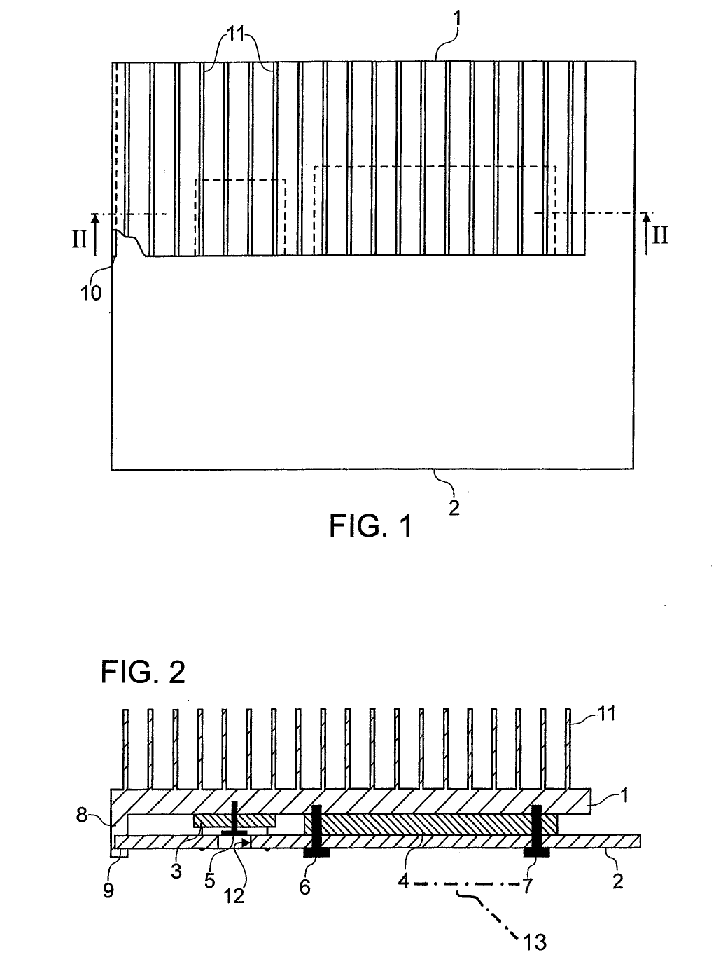

### DETAILED DESCRIPTION OF THE INVENTION

The present invention will be described in the following text with reference to rotation-speed electronics for a washing machine drive; it will be readily understood, however, that the invention can also be applied analogously to other power electronics as well, and the invention is not restricted to the specifically described, exemplary embodiment.

The heat sink 1 is an extruded part, for example composed of aluminium or some other metal with good thermal conductivity characteristics. The heat sink 1 comprises a base body in the form of a plate and from which a wall section 8 projects in one side area of the base body. A groove 9 is formed in this wall section 8. Furthermore, a multiplicity of cooling ribs or lamellae 11 are provided on the side of the heat sink 1 facing away from the wall section 8, in order to improve the cooling performance of the heat sink 1, in a known manner. Furthermore, a plurality of slots (not illustrated) are formed on the side of the heat sink 1 facing away from the cooling ribs 11.

The wall section 8, the groove 9, the cooling ribs 11 and the slots are all parallel to one another, so that the entire heat sink can be manufactured in a simple manner by way of one extrusion tool, as an extruded part. The extruded part does not need any further machining or treatment. All that is needed is for it to be cut to the desired length.

A printed circuit board 2 is mounted on the side of the heat sink 1 facing away from the cooling ribs 11. A plurality of components 3, 4 to be cooled, so-called power modules, as well as further components are mounted on this printed circuit board 2, with at least the power modules 3, 4 being mounted on the side of the printed circuit board 2 facing the heat sink 1. In the present exemplary embodiment, one of the power modules 3 is, for example, a bridge rectifier, and the other power module 4 contains, for example, three half-bridges and the associated drive circuit.

The printed circuit board 2 is pushed into the groove 9 in the wall section 8 of the heat sink, and is thus preinstalled on the heat sink 1. The distance between the groove 9 and the heat sink surface in this case defines the desired distance between the printed circuit board 2 and the heat sink 1, which corresponds approximately to the physical height of the components 3, 4 to be cooled. Furthermore, the printed circuit board 2 is provided with a stop 10, which defines the maximum insertion depth of the printed circuit board 2 into the groove 9, so that the printed circuit board 2 can also for this purpose be preinstalled in a predefined orientation relative to the heat sink 1.

One of the components 3 to be cooled is pressed directly against the heat sink 1, in order to produce a good thermal contact, by means of a self-tapping screw 5 as the attachment element according to the invention. The screw 5 is threaded into a corresponding slot in the heat sink 1. A bore or other aperture 12 is provided in the printed circuit board 2 for this purpose.

Two further self-tapping screws 6, 7 are provided as the attachment elements according to the invention for the other component 4 to be cooled. In contrast to the above component 3, this component 4 is, however, pressed by means of the screws 6, 7 against the heat sink 1 via the printed circuit board 2. On the one hand, this ensures good thermal contact between the component 4 to be cooled and the heat sink 1, while at the same time attaching the printed circuit board 2 to the heat sink 1.

In this case, self-tapping screws have been mentioned as preferred attachment elements 5, 6, and 7. However, the invention is not just restricted to them, and it is also possible to use other attachment elements, such as simple screws, bolts, rivets and the like.

As a result of the predefined position of the printed circuit board 2 in the groove 9 in the heat sink 1, the self-tapping screws 5, 6, 7 always automatically enter the slots in the lower face of the heat sink 1. There is no need to search for appropriate attachment holes in the heat sink 1. The components 3, 4 to be cooled are pressed against the heat sink 1 via the printed circuit board 2 by means of the attachment elements 5-7; there is no need for any additional attachment of the printed circuit board 2 to the heat sink 1.

In a preferred implementation of the power electronics, the printed circuit board 2 and the components 3, 4 are at least partially lacquered or encapsulated. A corresponding protective layer 13 is indicated at the bottom of FIG. 2.

The production of the heat sink 1 as an extruded part is simple, and the simple assembly of the printed circuit board 2 and heat sink 1 is suitable not only for manual assembly but also for automated assembly.

1. Power electronics, comprising:
a printed circuit board having mounted thereon at least one component to be cooled;
a heat sink disposed on said printed circuit board and in thermally conductive contact with the at least one component to be cooled;
a positioning device for positioning said printed circuit board in a defined orientation relative to said heat sink and with a spacing distance between said heat sink and said printed circuit board approximately corresponding to a physical height of the at least one component to be cooled; and
at least one attachment element for attaching said printed circuit board to said heat sink and for pressing the at least one component to be cooled against said heat sink.

2. The power electronics according to claim 1, wherein said positioning device includes a groove formed in a wall section of said heat sink, said groove being configured to receive said printed circuit board therein and being disposed at a predefined distance from a surface of said heat sink.

3. The power electronics according to claim 2, wherein said positioning device includes a stop formed on said printed circuit board, for defining an insertion depth of said printed circuit board into said groove.

4. The power electronics according to claim 1, wherein said at least one attachment element is a self-tapping screw.

5. The power electronics according to claim 4, wherein said heat sink has at least one slot formed therein on a side thereof facing towards said printed circuit board, and wherein said slot and said self-tapping screw are configured for said self-tapping screw to be screwed into said slot.

6. The power electronics according to claim 1, wherein at least one said attachment element presses the at least one component to be cooled against said heat sink via said printed circuit board.

7. The power electronics according to claim 6, wherein at least one further said attachment element presses at least one further component to be cooled directly against said heat sink.

8. The power electronics according to claim 1, wherein said heat sink is formed with a multiplicity of cooling ribs on a side thereof facing away from said printed circuit board.

9. The power electronics according to claim 1, wherein said heat sink is an extruded part with a multiplicity of parallel cooling ribs, one or more slots, a wall section, and a groove in said wall section extending parallel to one another.

10. The power electronics according to claim 1, wherein said printed circuit board and the at least one component are at least partially lacquered or encapsulated.

11. The power electronics according to claim 1 configured as power electronics for a washing machine drive.
